(19) United States
(12) Patent Application Publication
(10) Pub. No.: US 2004/0004482 A1
(43) Pub. Date: Jan. 8, 2004

(54) Industrial inspection using combination of functional testing and structural inspection

(75) Inventors: Joseph Bouabdo, Saint-Laurent (CA); Jerry Schlagheck, West Chester, OH (US); George Saati, Saint-Laurent (CA)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Photon Dynamics, Inc., San Jose, CA

(21) Appl. No.: 10/419,042

(22) Filed: Apr. 17, 2003

Related U.S. Application Data
(60) Provisional application No. 60/373,320, filed on Apr. 18, 2002.

(51) Int. Cl. G01R 31/28

(52) U.S. Cl. 324/501; 324/555; 250/341.6; 378/58

(57) ABSTRACT

There is described an inspection system for inspecting an object, the system comprising: a structural inspection module for inspecting the object structurally; a functional test module for testing the object functionally; a support device for supporting the object to be inspected structurally and tested functionally; and a common controller for the structural inspection module and the functional test module. A method for use with the system is also described.

### CROSS-REFERENCES TO RELATED APPLICATIONS

The present application claims priority to U.S. provisional application Serial No. 60/373,320 filed on Apr. 18, 2002 and entitled “Industrial Inspection Using Combination of Functional and Structural Imaging,” the content of which is incorporated herein by reference in its entirety.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to the field of industrial inspection, and more particularly to industrial inspection of manufactured objects using mass production techniques in which images of objects are acquired and analyzed automatically to detect defects as a quality control prior to product delivery.

It is commonly known that defects can and do occur during the manufacture of electronic Printed Circuit Board Assemblies (PCBAs). These defects can arise due to manufacturing process errors, such as misplacement of components, soldering related errors or misloading of component firmware, defective components, such as out-of-specification, or marginal, damaged, or bad components, or poor design. These defects inevitably lead to circuit opens, short circuits, or degraded circuit function or performance. In practice, methods and apparatus have been developed to detect defects prior to delivery of product. These methods and apparatus can generally be classified into two categories: structural and functional.

Structural detection comprises some form of inspection of the object in a non-operational, or non-functional, state. As such, structural methods and apparatus inspect the physical structure of the object. This is commonly done using visual techniques, either automated or manual, or X-Ray techniques, and characteristically images the object in some manner. Other variations are possible. Structural methods and apparatus are particularly suited for detecting structural defects such as component placement defects and component connection, or solder junction, defects.

Functional detection comprises some form of test of the object in an operational or functional state. As such, functional methods and apparatus test to ensure that the object is working as intended. This is commonly done using customized functional, or final, tests after assembly of the product is complete wherein the object is powered and a series of input signals are applied and corresponding output signals are detected and checked for correctness. A second common method and apparatus in this category is known as In-Circuit Test (ICT) wherein an array of test probes is used to individually power and input test signals to a plurality of components, or subcircuits, on the assembled, or partially assembled, object. Other variations are possible. Functional methods and apparatus are particularly suited, for detecting functional defects such as bad components and poor or marginal design problems.

Structural inspection rapidly and efficiently ferrets-out a large class of manufacturing defects early in the production process, before the PCBA is functional, thus providing for early and less costly correction of manufacturing processes and repair and recovery of product. However, structural inspection cannot detect all classes of defects and cannot be used as a final go/no-go quality check because it cannot determine if the product is working as intended. Functional tests can determine if the product is working as intended, however these tests must be used at or near the end of the production line where repair and recovery from defects are typically more costly. Further, test methods and apparatus can become very complex and costly for high-to-full levels of fault coverage. Some methodologies, such as final functional test, may provide little diagnostic information. Other methodologies, such as ICT, may be difficult to perform as component miniaturization and increasing component densities present probe access problems.

The present state of the art lacks a method and apparatus that can provide an increased level of confidence in the results of inspection. The existing systems and methods do not facilitate object diagnosis, they have a high total test time, and a low throughput. Therefore, it is essential to provide a method and system that can provide a broader fault coverage of an object and better diagnostic information.

### BRIEF SUMMARY OF THE INVENTION

According to a first aspect of the invention, an inspection system includes, in part, a structural inspection module for inspecting the object structurally; a functional test module for testing the object functionally; a support device for supporting the object to be inspected structurally and tested functionally; and a common controller for the structural inspection module and the functional test module.

Efficiencies are gained by integration of the hardware pertaining to the structural and test methodologies in a single apparatus wherein sharing of common elements, both structural and functional, are achieved (e.g. enclosure, test fixture, power supplies, computational resources). Such efficiencies result in reductions in cost, size and weight, and time to test.

Efficiencies are also gained by integration of the software pertaining to the structural and test methodologies in a single apparatus wherein sharing of common elements are achieved (e.g. control, display, data fusion and processing).

The inspection system combines an infrared (IR) verification system with a structural inspection system such as an Automated Optical Inspection System (AOI). The IR verification (IRV) system provides a basic functional test capability whereas the AOI system provides a capability to detect structural defects in areas of the board that do not display a significant thermal signature. It will be appreciated that this embodiment can detect many known types of failures in a single pass on most objects, thus reducing the time to test and consequently the cost of test per object.

Alternatively, there is provided a system for combining an IR verification system with a stimulated thermal imaging system (i.e. active IR system for inspection of the quality and integrity of hidden solder junctions of area array devices) wherein heat is selectively injected at specific locations on the object and changes in IR radiation emitted by the object in response to said thermal stimulation is recorded. The IRV system provides a basic functional test capability whereas the active IR inspection system provides a capability to inspect the hidden solder junctions of area array devices. It will be appreciated that this embodiment will provide increased fault coverage for PCBA's that contain a high proportion of area array devices, such as BGAs, detecting a large proportion of potential faults in a single pass, thus reducing the time to test and the cost of test. It will also be appreciated that this embodiment will reduce the time to repair and the cost of repair of faulty area array devices, such as BGAs, due to the additional information available for the analysis of these faults.

Also alternatively, there is provided a system for combining an IR verification system with an AOI system and a stimulated thermal imaging system (i.e. an active IR system for inspection of hidden solder junctions of area array devices, such as BGAs). The IRV system provides a basic functional test capability whereas the AOI system provides a capability to detect structural defects in areas of the board that do not display a significant thermal signature and which are not hidden from view, and the active IR inspection system provides a capability to inspect the hidden solder junctions. It will be appreciated that this embodiment provides a further increase in the capability to detect many known types of failures in a single pass, thus reducing the time to test and the cost of test per object.

In one embodiment, the inspection apparatus includes, in part, an IR imaging device, an optical imaging device, a support device for objects to be imaged at a same position by the IR and optical imaging devices, a common controller for the IR imaging device and the optical imaging device, and electrical supplies for providing electrical stimulation to the object. The support device may include a conveyor system that is also controlled by the common controller. It will be appreciated that the PCBA may also be imaged at two separate stations each, unique to the IR and the optical imaging systems, and that in this configuration two PCBAs may be imaged simultaneously.

According to a second aspect of the invention, there is provided a method for inspecting a PCBA, the method comprising: acquiring functional test data of the PCBA under conditions of electrical stimulation; acquiring structural inspection images of the PCBA; processing the functional test data and the structural inspection images to provide inspection information; and displaying the inspection information of the PCBA.

In one embodiment, there is provided a method for inspecting a PCBA, the method involving acquiring IR images of the PCBA under conditions of electrical stimulation, comprised of applied power and some combination of stimulating input signals and commands and/or built in test (BIT) signals, and acquiring visual images (i.e. optical images in the visible region of the electromagnetic spectrum) of the PCBA under non-stimulated conditions. The IR images are processed to provide functional test information. The optical images are processed to provide structural inspection information. Structural inspection is performed in areas or features of the PCBA that cannot be adequately tested by the functional test. Alternatively structural inspection is performed for the entire PCBA and the information combined with functional test information in regions of overlap provide defect detection results at a higher level of confidence. Alternatively, structural inspection can be cued to a specific region of interest by the functional test results to perform a more detailed inspection. Such combination of test and inspection can provide more detailed diagnostic information to facilitate failure analysis, root cause determination, and repair when a fault has been identified.

In another embodiment, there is provided a method for inspecting a PCBA, the method involving acquiring IR images of the PCBA under conditions of electrical stimulation, comprised of applied power and some combination of stimulating input signals and commands and/or built in test (BIT) signals, and separately under conditions of thermal stimulation. The IR images acquired under conditions of electrical stimulation are processed to provide functional test information. The IR images acquired under conditions of thermal stimulation are processed to provide structural information, more specifically to provide information concerning the quality and integrity of hidden solder junctions. The IR images for both systems can be acquired at the same station using the same IR imaging device. Structural testing is performed for those areas or features of the PCBA that cannot be adequately tested by the functional test, such as for inspection of hidden solder junctions of area array devices, such as BGAs. Information can be combined with functional test information for said area array devices to provide defect detection results at a higher level of confidence. Such combination of test and inspection can provide more detail diagnostic information to facilitate failure analysis, root cause determination, and repair when a fault has been identified.

In yet another embodiment, there is provided a method for inspecting a PCBA, the method involving acquiring IR images of the PCBA under conditions of electrical stimulation, comprised of applied power and some combination of stimulating input signals and commands and/or built in test (BIT) signals, and separately under conditions of thermal stimulation, and acquiring visual images (i.e. optical images in the visible region of the electromagnetic spectrum) of the PCBA under non-stimulated conditions. The IR images acquired under conditions of electrical stimulation are processed to provide functional test information. The IR images acquired under conditions of thermal stimulation are processed to provide structural information, more specifically to provide information concerning the quality and integrity of hidden solder junctions. The IR images for both systems can be acquired at the same station using the same IR imaging device. The optical images are processed to provide structural inspection information generally. Structural inspection is performed for those areas or features of the PCBA that cannot be adequately tested by the functional test, such as for inspection of hidden solder junctions of area array devices, such as BGAs, or areas of negligible heating under conditions of electrical stimulation. Alternatively, structural inspection information can be combined with functional test information for said area array devices to provide defect detection results at a higher level of confidence. Alternatively, structural inspection generally can be performed for the entire PCBA and the information combined with functional test information in regions of overlap provide defect detection results at a higher level of confidence. Alternatively, structural inspection can be cued to a specific region of interest by the functional test results to perform more detailed inspection. Such combination of test and inspection can provide more detailed diagnostic information to facilitate failure analysis, root cause determination, and repair, when a fault has been identified.

According to a third aspect of the invention, there is provided an inspection apparatus comprising an IR imaging device, an optical imaging device, an IR image analyzer and an optical image analyzer, wherein at least one of the image analyzers receives data from another of the image analyzers to improve an image analysis result. Information obtained from optical imaging about the position of a component within the PCBA under test is used by the IR image analyzer to identify an anomalous component.

The inspection apparatus includes, in part, an IR imaging device, a heat source for providing (i.e. generating and directing) a thermal stimulation to the object, a support device for objects to be imaged at a same position by the IR and stimulated thermal inspection systems, a common controller for the IR the stimulated thermal inspection systems, and electrical supplies for providing electrical stimulation to the object. The support device may include a conveyor system that is also controlled by the common controller. It will be appreciated that the PCBA may also be imaged at two separate stations each unique to the IRV and the stimulated thermal inspection systems, and that in this configuration two PCBAs may be imaged simultaneously.

In another embodiment, the inspection apparatus includes, in part, an IR imaging device, or devices, an optical imaging device, a heat source for providing (i.e. generating and directing) a thermal stimulation to the object, a support device for objects to be imaged at a same position by the IR and optical imaging devices, a common controller for the IR, the stimulated thermal inspection, and the optical imaging systems, and electrical supplies for providing electrical stimulation to the object. The support device may include a conveyor system that is also controlled by the common controller. It will be appreciated that the PCBA may also be imaged at two or three separate stations each unique to, or some combination of, the IRV, the stimulated thermal inspection, and the optical imaging systems, and that in this configuration two or three PCBAs may be imaged simultaneously.

In yet another embodiment, there is provided an inspection apparatus that includes, in part, an IR imaging device, or devices, an optical imaging device, an IR image analyzer, associated with the IRV system, an IR image analyzer, associated with the active IR system, and an optical image analyzer, wherein at least one of the image analyzers receives data from another of the image analyzers to improve image analysis result. Information obtained from optical imaging about the position of a component within the PCBA under test is used by the IR image analyzer to identify an anomalous component.

### BRIEF DESCRIPTION OF THE DRAWINGS

The invention will be better understood by way of the following detailed description of a preferred embodiment with reference to the appended drawings, in which:

FIG. 1 is a simplified block diagram of an embodiment of the system in accordance with one embodiment of the present invention;

FIG. 2 is a schematic diagram of an imaging device apparatus according to an embodiment using combination of IR and visual imaging; and

FIG. 3 is a flowchart of the method according to an embodiment of the present invention.

### DETAILED DESCRIPTION OF THE INVENTION

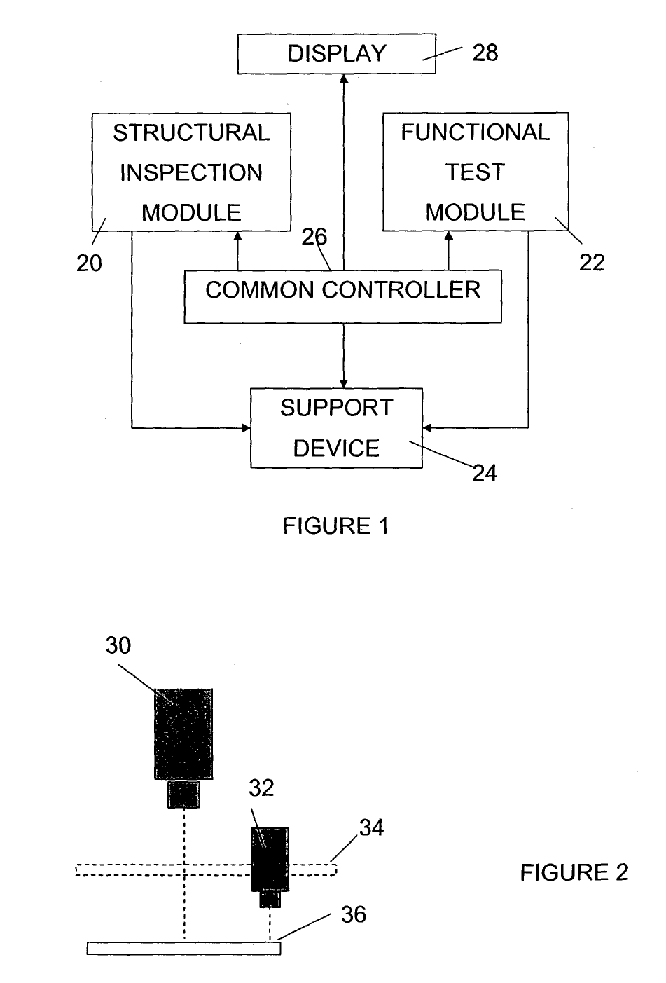

FIG. 1 is a block diagram of an inspection system in accordance with one embodiment of the present invention. The inspection system of FIG. 1 is shown as having, in part, a structural inspection module 20, and a functional test module 22. Both structural inspection module 20 (hereinafter alternatively referred to as module 20) and structural inspection 22 (hereinafter alternatively referred to as module 22) are adapted to inspect an object positioned on the support device 24. A common controller 26 controls both the structural inspection module 20 and the functional test module 22.

The support device 24 may include a conveyor also controlled by the common controller 26. The conveyor may serve two purposes. When the structural inspection and functional testing require an IR imaging device and a non-IR imaging device, respectively, the conveyor can displace the objects under inspection from a first position, where the structural inspection takes place, to a second position, where the functional test takes place. In this case, the imaging device (i.e. camera) cannot be shared between the two inspection modules. Therefore, the object is moved from one position to another via the conveyor.

Alternatively, the cameras can be moved back and forth to allow the IR and non-IR imaging devices each a turn at imaging the object without having to displace the object during the entire inspection process. To move the cameras, the embodiment shown in FIG. 2 can be used. An IR camera 30 is fixed and a vision camera 32 is mounted onto an x-y camera gantry 34 to be moved in and out of position beneath the IR camera to image the PCB assembly under test.

For the embodiment where the cameras are moved, the conveyor may simply be used to advance the objects one at a time into an apparatus for inspection and out of the apparatus once the inspection is complete. The process is then automated. When there is more than one camera present, the conveyor can hold a multitude of objects such that the inspection can occur concurrently on more than one object.

As seen in FIG. 1, the inspection system may further include a display 28 for receiving the inspection or test results from the controller 24 and displaying them. The controller 24 may provide the test results for each individual test to the display 28 separately, or integrate the results together. In this case, the separate test results are used by the controller 24 to generate a more comprehensive set of data wherein the structural inspection and functional test are used in a complementary manner. The information is combined to provide broader fault coverage of the object and to increase the level of confidence in the results of the inspection in regions of overlapping coverage. Alternatively, the use of the test information in a combined manner may be done so as to eliminate overlapping coverage of the two types of inspection. This is done to reduce the total test time and to increase throughput.

The apparatus according to the preferred embodiment comprises an IR verification system with all its components and an AOI system with all of its components, integrated in a single unit, with possible shared common hardware elements and a possible single controlling software application. Separate image processing and display applications may be used. Integration of alternate structural inspection systems such as X-ray imaging is possible. Integration of alternate functional test systems is possible.

The IR verification system, by means of measuring the IR radiation emanating from a PCBA when electrically stimulated by application of a power source and possibly some combination of signal and/or control inputs, also known as the thermal signature, and comparing said thermal signature with that of a defect-free PCBA, provides a measure of the proper functioning of the PCBA. The IR verification system may be made in accordance with the IR screening and inspection system described in U.S. Pat. No. 5,808,303, which is hereby incorporated by reference in its entirety.

The AOI system checks for the presence and proper placement of components on the PCBA, and the quality and integrity of the visible solder junction connections between the components and the PCB. The AOI system is adapted to inspect components and their solder junctions, which may not be tested by the IR verification system due to lack of thermal activity in that part of the circuit under conditions of the applied electrical stimulation.

Additionally, a stimulated thermal imaging system (i.e. an active IR system for inspection of hidden solder junctions of area array devices, such as BGAs) is also provided for structural testing along with the AOI system. The IRV system provides a basic functional test capability whereas the AOI system provides a capability to detect structural defects in areas of the board that do not display a significant thermal signature and which are not hidden from view. The active IR inspection system provides a capability to inspect the hidden solder junctions. The structural inspection module comprising the AOI and the active IR systems may be made in accordance with U.S. Pat. No. 6,272,204, which is hereby incorporated by reference in its entirety.

In one embodiment, the PCBA under test enters the test chamber automatically via a conveyor subassembly. In another embodiment, the PCBA may be placed in the test chamber manually. The PCBA is first imaged by the AOI system. The AOI imaging camera is moved out of the field of view of the fixed IR camera, electrical stimulation is applied, and the PCBA is imaged by the IRV system. Alternately, application of electrical stimulation and IR imaging may be performed first followed by AOI imaging. The PCBA under test then exits the system via the conveyor subassembly. In an alternate embodiment, the PCBA may be removed by the system manually. Image processing and analysis is performed on the two sets of data. The results are assimilated, recorded, and displayed to the operator. If a defect is detected, the PCBA is flagged and off-lined for failure analysis and repair. A list of suspected defects may be provided.

In a second embodiment, the PCBA may be positioned at a first station where one of AOI or IR imaging is performed, followed by movement of the PCBA to a second station where the other of IR or AOI imaging is performed, both stations contained within the single test unit.

The first embodiment provides design efficiencies inherent in the usage of a common test station by both the IR and AOI (i.e. functional and structural) imaging systems. The second embodiment provides operational efficiencies inherent in the simultaneous imaging, by both systems, of two separate PCBA resulting in reduced time to test, hence increased throughput.

By combining functional and structural inspection systems in a single apparatus, in accordance with the present invention, improvements in fault coverage, confidence level, and efficiencies in operation are realized.

Hardware design efficiencies are achieved by sharing of common design elements including, for example, structural subassemblies (e.g. outer shell), mechanical subassemblies (e.g. conveyor subsystem and/or fixturing), electrical subassemblies (e.g. power supplies and power distribution system), computing subassemblies (e.g. common PC and operating system and peripherals including monitor, keyboard, memory modules, network cards, R/W CD drives, and printers).

Software design efficiencies are also achieved by sharing of a common operating system and system architecture. A common controller is used to coordinate and control common functions including, for example, system housekeeping tasks, external communications interface, data management and display. The common controller also coordinates the operation of the two independent modules used for operation, control, and unique processing functions of the IR and AOI imaging systems comprising, for example:

AOI application to control the vision camera and its x-y gantry or table servo movement, manage AOI specific processing and data analysis;

IR verification application to control the IR camera, application of the electrical stimulation to the PCBA under test, and IR specific processing and data analysis.

The results of AOI and IR (i.e. structural and functional) data processing and analysis are fed to a common processing module for fusion and post processing of the results to take advantage of potential synergies inherent in the combination of the date comprising, for example:

Usage of AOI data to specifically identify components that have been indicated to be anomalous by the IR system;

Specific detailed inspection of components that have been indicated to be anomalous by the IR system, thus indicating if said anomaly has an obvious structural defect (e.g. lifted lead, misplaced, missing, or wrong component), or if not, indicating that said anomaly may be a bad component, or, in conjunction with other anomalies, an effect of a defect contained in another part of the PCBA, thus providing additional valuable diagnostic information for later failure analysis and root cause determination, and defect calls at an increased level of confidence;

Selective structural testing only over a portion of the PCBA not covered adequately by the IR testing, unless anomalies are detected by the IR system as indicated above, thus reducing time to test, while at the same time, providing increased fault coverage;

Usage of the AOI data to provide automated alignment of images for the IR imaging system, thus facilitating comparison of PCBAs under test with reference models.

Following combined data processing, the common controller controls data management, storage and display of the combined results. For example, one display option is to display the AOI images while overlaying symbology indicating components or areas of anomalous thermal behavior.

One possible sequence of operation according to an embodiment of the present invention is as follows (alternate sequences are possible):

1. the PCBA is presented to the apparatus at one end,

2. the common controller senses the presence of the board and moves the conveyor so as to transport the PCBA to a first station,

3. the AOI application is launched and the PCBA is structurally inspected,

4. the AOI application module moves the vision camera in a predetermined manner using an X-Y gantry,

5. the AOI application module gathers, processes, and analyses the optical imagery data and sends the results to the main controller,

6. the controller transports the PCBA to a second station,

7. IRV application is launched and the PCBA is functionally tested,

8. the IRV application module raised a bed-of-contacts to apply electrical stimulation to the PCBA,

9. the IRV application module gathers, processes, and analyses the IR imagery data and sends the results to the main controller,

10. the main controller combines and post processes the data in a predetermined manner, stores, displays the final results to the operator, and provides a flag or automated signal to indicate if the PCBA has failed the inspection/test,

11. the common controller moves the conveyor so as to transport the PCBA out of the apparatus.

Although the aforementioned sequence of operation describes a configuration wherein AOI and IR imaging is performed at separate test stations in the apparatus, it is understood that other configurations are possible such as illustrated in FIG. 2 which shows movement of the cameras to allow both imaging systems to operate using a common imaging station.

In another embodiment, selected structural inspection is achieved by means of IR imaging of a top surface of a component while injecting a thermal pulse (heating or cooling) into, or in near proximity to, the component. Changes in the signature of the IR radiation measured from that of a known defect-free component is indicative of the presence of a defect, said defect disturbing the normal diffusion of heat from the point of thermal stimulation, or heat injection, to the radiating top surface, or from the radiating top surface if said thermal stimulation is injected into the top surface. The thermal stimulation may be at one or more selected locations on the PCBA surface. In the case of sufficiently thin objects, the heat pulse may be injected on a side of the object that is opposite to that of the surface that is imaged. In this case, the heat diffuses through the component and the IR radiation from the component's top surface is measured, said diffusion potentially occurring across a solder junction of interest. In this embodiment, the thermal stimulation, or heat pulse, is provided by a laser beam that is directed at the selected location on the object by a beam control mechanism, such as a galvanometer. Other means are possible to direct the thermal stimulation to the selected location, such as, for example, using a mechanism that can be precisely positioned in an x-y plane to physically move the laser or a fiber optic pigtail connected to the laser. Other means are possible to provide a source of thermal stimulation, such as a flash lamp, or a hot or cold mechanical contact.

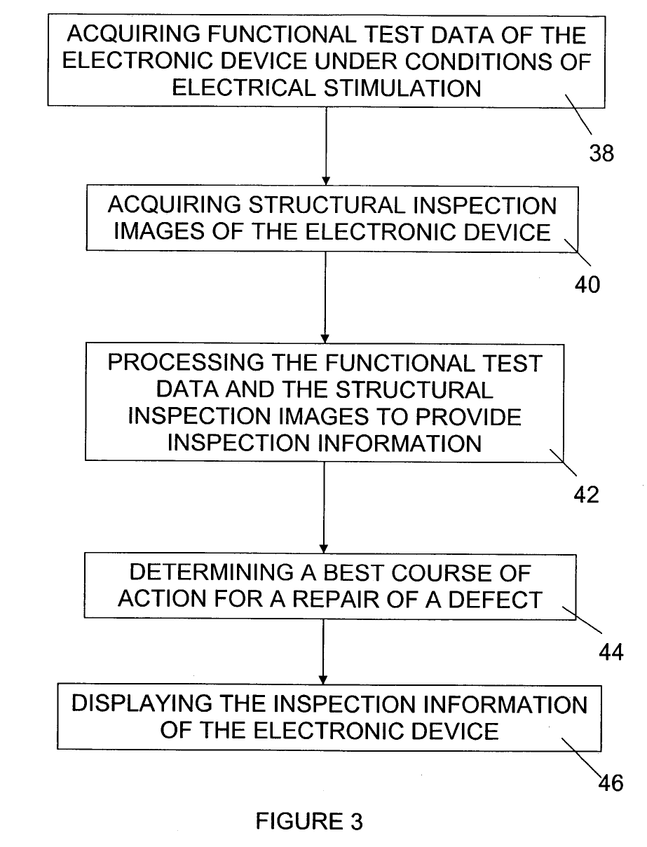

FIG. 3 is a flow chart of the steps involved according to an embodiment of the invention. In step 38, functional test data of the PCBA is acquired while the device is under conditions of electrical stimulation. The electrical stimulation may be done by using a bed of nails, which comes up under the PCBA and connects to its inputs. The functional test data may then be acquired by either taking IR images of the PCBA while it is being electrically stimulated, or simply by processing output data of the PCBA. In step 40, structural inspection images of the PCBA are then acquired. This can be done by acquiring optical images in the visible region of the electromagnetic spectrum. Alternatively, the structural inspection images are acquired while applying thermal stimulation to the PCBA and the images are acquired by imaging IR radiation emitted by the PCBA. The thermal stimulation may be done by selectively injecting heat at specific locations on the PCBA. In another embodiment, acquiring structural inspection images comprises combining IR and non-IR imaging to obtain a set of structural inspection images.

In step 42, the functional test data and structural inspection images are then processed to provide inspection information. This processing may comprise combining the functional test data and data obtained from the structural inspection images to provide more comprehensive inspection data. For example, the functional test data may be used to identify a potential defect and the structural inspection images are used to confirm the potential defect. Another example is to combine the two types of tests in a manner so as to eliminate overlapping coverage of the PCBA. In step 44, a best course of action is determined for repairing an identified defect. Providing a best course of action is understood as providing the technician repair with instructions in a convenient means, thus speeding up the repair process. In step 46, the inspection information is then displayed on a displaying device.

It will be understood that numerous modifications thereto will appear to those skilled in the art. Accordingly, the above description and accompanying drawings should be taken as illustrative of the method and apparatus of the invention and not in a limiting sense. It will further be understood that it is intended to cover any variations, uses, or adaptations of the invention following, in general, the principles of the invention and including such departures from the present disclosure as come within known or customary practice within the art to which the invention pertains.

What is claimed is:

1. An inspection system for inspecting an object, said system comprising:
a structural inspection module adapted to inspect said object structurally;
a functional test module adapted to test said object functionally;
a support device adapted to support said object; and
a common controller adapted to control said structural inspection module and said functional test module.

2. An inspection system as claimed in claim 1, wherein said functional test module comprises an infrared verification system.

3. An inspection system as claimed in claim 2, wherein said structural inspection module comprises an automated optical inspection system.

4. An inspection system as claimed in claim 2, wherein said structural inspection module comprises an X-Ray inspection system.

5. An inspection system as claimed in claim 2, wherein said structural inspection module comprises an active infrared system.

6. An inspection system as claimed in claim 5, wherein said structural inspection module and said functional test module share an infrared imaging device.

7. An inspection system as claimed in claim 5, wherein said structural inspection module further comprises an automated optical imaging system.

8. An inspection system as claimed in claim 1, wherein said functional test module comprises an in-circuit testing system and said structural inspection module comprises one of an x-ray inspection system, an automated optical imaging system, and an active infrared system.

9. An inspection system as claimed in claim 1, wherein said support device includes a conveyor system that is controlled by said common controller.

10. An inspection system as claimed in claim 9, wherein said conveyor displaces said objects to be at one of a first position for an infrared imaging and a second position for a non-infrared imaging.

11. An inspection system as claimed in claim 10, wherein said conveyor is adapted to hold a second object, said inspection system adapted to inspect the first and second objects concurrently.

12. An inspection system as claimed in claim 1, further comprising a display for receiving test results from said controller and displaying said results.

13. An inspection system as claimed in claim 12, wherein said controller provides results of said structural inspection and results of said functional test separately to said display.

14. An inspection system as claimed in claim 12, wherein said controller integrates results of said structural inspection and results of said functional test and provides said results to said display in an integrated form.

15. An inspection system as claimed in claim 9, wherein said controller comprises an aligning module to align said object in a desired position by controlling said conveyor.

16. An inspection system as claimed in claim 1, wherein said controller comprises a processing module for utilizing said structural inspection module to identify anomalies detected by said functional test module.

17. An inspection system as claimed in claim 1, wherein each of said structural inspection module and said functional test module has an associated data acquisition component and an associated data analysis component, and wherein the data acquisition component associated with one of said structural inspection module and said functional test module modifies data acquisition in response to information received from a data analysis component associated with the other one of said structural inspection module and said functional test module.

18. An inspection system as claimed in claim 1, wherein said controller integrates results of said structural inspection and results of said functional test to perform a analysis of said integrated results.

19. An inspection system as claimed in claim 18, wherein said controller generates a defect call using a correlation of said structural inspection results and said functional test results.

20. An inspection system as claimed in claim 9, wherein said inspection system is disposed in a single housing.

21. A method for inspecting a printed circuit board assembly, the method comprising:
acquiring functional test data of said printed circuit board assembly under conditions of electrical stimulation;
acquiring structural inspection images of said printed circuit board assembly;
processing said functional test data and said structural inspection images to provide inspection information; and
displaying said inspection information of said printed circuit board assembly.

22. A method as claimed in claim 21, wherein said acquiring functional test data and said acquiring structural inspection images is done at a same station using a same imaging system.

23. A method as claimed in claim 21, wherein said processing said functional test data and said structural inspection images comprises combining said functional test data and said structural inspection images to provide inspection information of said printed circuit board assembly.

24. A method as claimed in claim 23, wherein said combining comprises combining to provide a broader fault coverage of said printed circuit board assembly than if said structural inspection and said functional test were used independently.

25. A method as claimed in claim 23, wherein said processing said functional test data and said structural inspection images comprises identifying a potential defect using said functional test data, and using said structural inspection images to confirm said potential defect, whereby an increased level of confidence is obtained for regions of overlapping coverage.

26. A method as claimed in claim 21, further comprising a step of determining a best course of action to repair a defect.

27. A method as claimed in claim 23, wherein said combining said functional test data and said structural inspection images comprises combining in a manner so as to eliminate overlapping coverage of said printed circuit board assembly, whereby total test time is reduced and throughput is increased.

28. A method as claimed in claim 21, wherein said acquiring functional test data comprises obtaining infrared images while applying electrical stimulation to said printed circuit board assembly.

29. A method as claimed in claim 21, wherein said acquiring structural inspection images comprises acquiring optical images in a visible region of an electromagnetic spectrum.

30. A method as claimed in claim 21, wherein said acquiring structural inspection images comprises applying thermal stimulation to said printed circuit board assembly and imaging infrared radiation emitted by said printed circuit board assembly.

31. A method as claimed in claim 30, wherein said applying thermal stimulation comprises selectively injecting heat at specific locations on said printed circuit board assembly.

32. A method as claimed in claim 31, wherein said applying electrical stimulation comprises using a bed of nails under said printed circuit board assembly.

33. A method as claimed in claim 21, wherein said acquiring structural inspection images comprises combining infrared and non-infrared imaging to obtain said images.

34. A method as claimed in claim 21, wherein said displaying comprises displaying images resulting from said functional test data and said structural inspection data in an overlapped fashion, whereby fault diagnosis is facilitated.
